(19) United States
(12) Patent Application Publication
(10) Pub. No.: US 2012/0215373 A1
(43) Pub. Date: Aug. 23, 2012

(54) PERFORMANCE OPTIMIZATION IN COMPUTER COMPONENT RACK

(75) Inventors: Brian Koblenz, Seattle, WA (US); Timothy J. Cox, Oak Point, TX (US); William Sulzen, Research Triangle Park, NC (US)

(73) Assignee: CISCO TECHNOLOGY, INC., San Jose, CA (US)

(21) Appl. No.: 13/029,450

(22) Filed: Feb. 17, 2011

(51) Int. Cl. G05D 23/00; H05K 7/20

(52) U.S. Cl. 700/300

(57) ABSTRACT

A system and method are provided for use with a containerized data center that includes a rack, at least one computer component disposed within the rack, at least one sensor to measure an operating condition associated with the at least one computer component within the rack, a database including a plurality of algorithms configured to control environmental conditions of the at least one computer component within the rack, and an environmental control system to control environmental conditions for the computer component within the rack. In response to the measured operating condition associated with the at least one computer component within the rack falling outside of a setpoint range, thermal treatment of the computer component is achieved utilizing an algorithm that is selected from the database to control the environmental control system.

### TECHNICAL FIELD

The present disclosure relates to environmental control within one or more computer component racks, such as computer component racks in containerized data centers.

### BACKGROUND

Data centers include a large number of computer components to store and process data (e.g., server equipment, data storage equipment, networking equipment, etc.). In recent years, data centers have undergone changes with regard to how the centers can be constructed, organized and managed. In particular, recent developments in data centers employ a modular or containerized design in which racks which house computer components are arranged within containers. This design maximizes computing capacity while at the same time minimizing the space requirements for the hardware. Providing large numbers of computer components in a modular, containerized design presents a number of challenges, including providing proper ventilation and cooling systems that optimize the performance of the computer components.

Examples of typical cooling systems for computer component racks utilize air fans and/or water or other liquid cooling systems that provide cooling to the components within racks or cooling within containers that house multiple racks. Such cooling systems typically employ temperature sensors and/or other types of sensors that provide feedback control of the cooling system to facilitate some level of temperature adjustment and control within the racks or the container. Many computer component racks employ a temperature control algorithm that adjusts air fan speed or coolant liquid flow rate based upon a measured temperature within a rack or within a containerized system including a plurality of racks. However, such cooling systems are limited in that they cannot dynamically control temperature on an individualized basis for different racks based upon a number of different algorithms or policies.

### BRIEF DESCRIPTION OF THE DRAWINGS

FIG. 1 is a schematic block diagram of an example system including a containerized data center farm coupled with an environmental control system.

FIG. 2 is a schematic block diagram of an example rack with a plurality of computer components and a cooling system for the rack.

FIG. 3 is a flow chart that depicts an example process for operating the system of FIG. 1.

FIG. 4 is a block diagram for an example control system that performs the control processes described herein.

### DESCRIPTION OF EXAMPLE EMBODIMENTS

### Overview

A system and method are provided for use with a containerized data center that includes a rack, at least one computer component disposed within the rack, at least one sensor to measure an operating condition associated with the at least one computer component within the rack, a database including a plurality of algorithms configured to control environmental conditions of the at least one computer component within the rack, and an environmental control system to control environmental conditions for the computer component within the rack. In response to the measured operating condition associated with the at least one computer component within the rack falling outside of a setpoint range, thermal treatment of the computer component is achieved utilizing an algorithm that is selected from the database to control the environmental control system.

### Example Embodiments

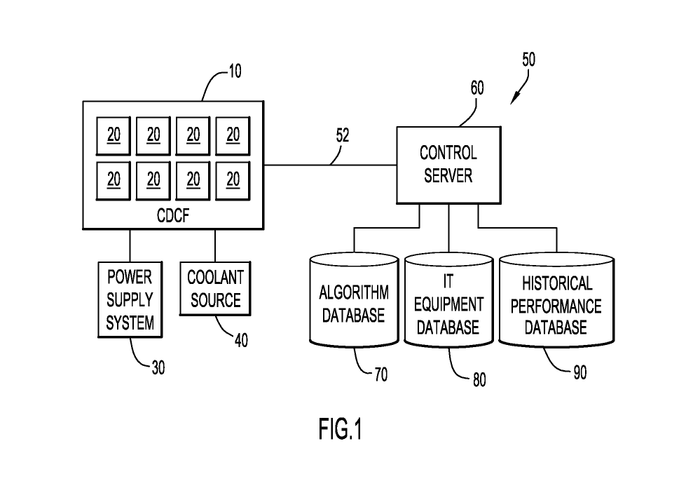

Referring to FIG. 1, a block diagram is shown for an example containerized data center farm (CDCF) 10 coupled with an environmental control system 50. The CDCF 10 is an enclosed structure that houses a plurality of containers 20. The CDCF 10 can be stationary (e.g., a building or other fixed structure) or, alternatively, mobile (e.g., a portable container). The containers 20 include a plurality of computer components that are secured within the container in a suitable manner, e.g., by stacking the components within the containers. The computer components can be further compartmentalized within containers 20, where each container 20 is a containerized data center (CDC) 10 that includes a plurality of storage racks. Each rack includes one or more computer components in a stacked configuration inside the rack. The computer components stored within the containers 20 of the CDCF 10 can be any form of hardware associated with processing, storage and/or communication of data including, without limitation, server equipment, data storage equipment and networking equipment. A power supply system 30 connects with the CDCF 10 to provide electrical power for operation of the various computer components as well as other devices within the CDCF. Optionally, a coolant source 40 can also be connected with the CDCF 10 to provide a source of coolant for temperature control within the containers 20 as described in more detail below. In certain embodiments, the power supply system 30 and coolant source 40 can also be integrated within the CDCF 10. The CDCF can further be configured to connect, via any suitable communication connection or link (e.g., via a local or wide area network) to other systems to facilitate transfer of data between the CDCF 10 and the other systems.

The CDCF 10 is further coupled via a suitable communication link 52 with the environmental control system 50. The environmental control system 50 controls how and when computer components within the containers 20 are thermally treated based upon different algorithms which are set by policies based upon particular container/rack configurations or other scenarios. The CDCF 10 is coupled with the environmental control system 50 via link 52 in any suitable manner to facilitate transfer of information between the two systems. Examples of the link 52 between the CDCF 10 and the environmental control system 50 include, without limitation, a local area network, a wide area network (e.g., via the Internet), any one or more wired and/or wireless links, etc. The environmental control system 50 includes a control server 60 that communicates with one or more local controllers and/or sensors disposed within the CDCF 10 and associated with thermal treatment units configured to cool computer components within the containers 20. The server 60 is further coupled with one or more databases that provide information relating to providing temperature control to the computer components in the CDCF 10. In the example embodiment of FIG. 1, information relating to control algorithms for providing temperature control to local controllers associated with the containers 20 is stored in an algorithm database 70, information relating to the computer components in the containers 20 is stored in information technology (IT) database 80, and information relating to historical performance of computer components located in specific containers 20 is stored in historical performance database 90. Alternatively, it is noted that all of the information can also be stored within a single database. In addition, while the environmental control system 50 is shown in FIG. 1 as being coupled with a single CDCF 10, it is noted that the system 50 could also be coupled with a plurality of CDCFs (located in one or more geographic locations). The system 50 could also be coupled to one or more separate rack structures or to one or more separate containerized data centers (CDCs) (located in one or more geographic locations).

The computer components are located within rack structures within the CDCF 10. It is noted that the containers 20 themselves can be the rack structures or, alternatively, the containers 20 can be containerized data centers which house one or more rack structures. In a scenario in which the containers are simply separate rack structures, the unit 10 storing the containers would be a containerized data center (CDC) rather than a containerized data center farm (CDCF).

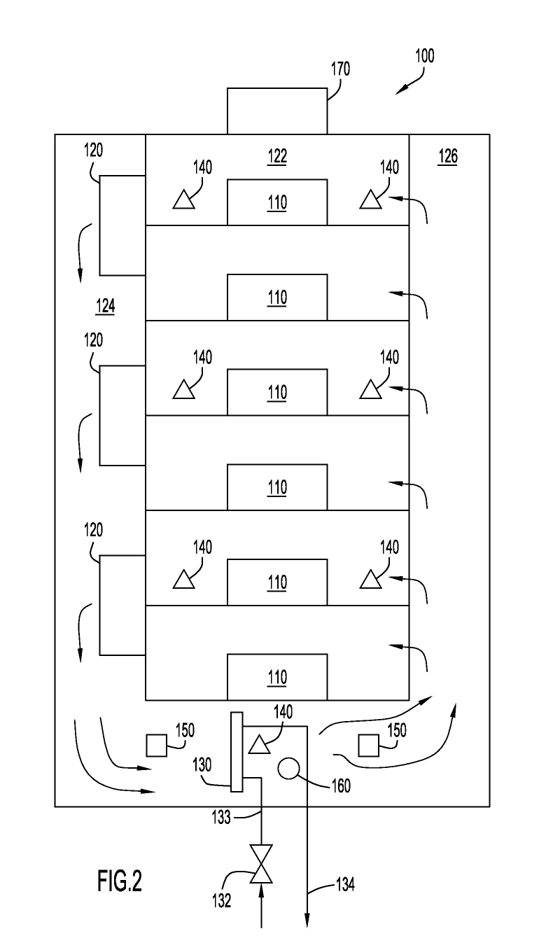

An example configuration of a rack structure is shown in the schematic diagram FIG. 2. Computer components 110 are housed in a stacked manner within an internal compartment of a rack 100. The components can be servers, data storage devices, networking devices or any other form of hardware. The cooling system for the rack 100 includes a plurality of fan units 120 that direct cooling air in a circuit through the rack 100 so as to flow toward the computer components 110. Although three fan units 120 are shown in FIG. 2, it is noted that any suitable number of fan units can be provided to achieve cooling within the rack 100. In addition, while the rack is shown in FIG. 2 with computer components stacked and fan units aligned in a vertical orientation, it is noted that the rack can have any other suitable configuration (e.g., fan units and computer components of the rack can be stacked or segregated in any horizontal, vertical and/or other alignments with respect to each other).

The fan units are configured with different operating speeds to selectively direct air at different flow rates from the fan outlets. As shown in FIG. 2, the fan units 120 are disposed within a hot aisle chamber 124. The fan units 120 pull or draw air from an equipment chamber 122 located centrally within the rack 100 in which the computer components 110 are disposed and into the hot aisle chamber 124, where the arrows depicted in FIG. 2 show the airflow cooling circuit or airflow path that is generated by the fan units. The fan units 120 direct air flow through the hot aisle chamber 124 to a coolant flow conduit 130. Air flowing past the coolant flow conduit 130 is directed into a cold aisle chamber 126, where it then flows back into the equipment chamber 122 (as shown by the arrows in FIG. 2). The hot aisle chamber 124, which includes the fan units 120, can further be constructed as a door that is pivotally movable away from the equipment chamber 122 in order to provide easy access to the fan units.

A coolant flow system is also provided within the rack 100 and includes the coolant flow conduit 130. The coolant flow conduit 130 provides heat exchange between a coolant (e.g., water) flowing through the conduit 130 and the air streams directed from the fan units 120 through the hot aisle chamber 124 toward and across the conduit 130 (e.g., to lower the temperature of the air flowing from the fan units prior to being re-directed into the cold aisle chamber 126 and back into the equipment chamber 122 and toward the computer components 110). The coolant flow conduit 130 is connected with coolant source 40 (shown in FIG. 1), where the coolant source 40 provides the coolant at a selected temperature or within a selected temperature range to the rack 100. Thus, air flowing within the cold aisle chamber 126 has been cooled by the coolant system, while air flowing through the equipment chamber 122 cools the computer components 110 and is drawn into the inlets of the fan units 120. The warmer air that has been directed across the computer components 110 is again re-directed through the hot aisle chamber 124 and across the coolant conduit 130 so as to cool the air prior to re-entering the equipment chamber 122 of the rack 100.

Temperature and/or pressure sensors (shown schematically as elements 140) are provided at different locations within the equipment chamber. The temperature sensors are provided at suitable locations to measure the hot aisle and cold aisle temperatures and/or temperatures at any other locations within the rack 100 so as to effectively measure temperature gradients that may exist within the rack. Optionally, pressure sensors can also be provided at suitable locations to measure pressures and/or pressure gradients within the equipment chamber 122 (e.g., to determine whether there are stagnant or stalled air flows within the equipment chamber). In addition, the coolant conduit 130 includes temperature sensors to measure the temperature of the liquid coolant at an inlet location 133 and an outlet location 134 of the rack. One or more valves (shown generally as valve 132 in FIG. 2) can also be provided to control the flow rate of liquid coolant through the conduit and between the rack inlet and outlet locations. Humidity sensors 150 are also provided at one or more suitable locations within the rack 100 (e.g., at one or more locations proximate the coolant conduit 130) to measure humidity levels of the air circulating within the rack. The combination of temperature, pressure and humidity measurements within the rack facilitate the monitoring and control of environmental conditions within the rack.

One or more leak detection sensors (indicated generally as element 160 in FIG. 2) are also provided within the rack 100 at one or more suitable locations to identify whether the conduit 130 is leaking coolant at any time during operation of computer components within the rack. In particular, the leak detection sensor is disposed within the rack, while flow valve(s) 132 for the coolant conduit 130 are disposed external to the rack so as to ensure coolant flows are prevented from flowing within the rack in the event a coolant leak is detected.

Other types of sensors (including, without limitation, airflow sensors) can also be provided at suitable locations within the rack 100 to assist in monitoring environmental conditions within the rack and enhance temperature control by controlling the fan units and coolant flow system during system operation. The temperature sensors, humidity sensors, pressure sensors, leak detection sensors and other types of sensors provided within the rack can be of any one or more conventional or other suitable types.

In addition, sensors are provided to measure the processing workload (also referred to as “IT load” or “IT workload”) of computer components 110 within the rack 100 at any given time. One or more sensors can be provided for a rack to monitor the IT load individually for each computer component 110 within the rack, to monitor the IT load for selected sets or groups of computer components within the rack or, alternatively, to monitor the entire or collective workload of all the computer components within the rack. In an example embodiment, power consumption sensors are provided to measure the electrical power requirements for computer components within the rack either continuously or over any selected time period, and this provides an indication of the degree at which computer components are processing data (and thus generating heat) within the rack. However, other types of sensors can also be utilized to measure the IT loads for computer components within the rack (e.g., central processor unit loading and/or other types of sensors or detection systems that monitor the transfer and/or processing of data in relation to a particular component, that monitor the activity of processors and/or other sub-components within the computer components, etc.).

Direct control of operation of the fan units and coolant flow system can be achieved via local controllers connected with each rack, where the local controllers communicate (via the communication link 52) with the server 60 of the environmental control system 50. For example, as shown in FIG. 2, the rack 100 includes a controller 170 that communicates with the various rack sensors and provides temperature and/or other environmental control within the rack, by controlling operation of the fan units 120 and the coolant flow system for the rack 100, based upon a particular algorithm assigned to the rack. The controller 170 implements an algorithm (e.g., by accessing a control algorithm from database 70) for controlling the fan units and coolant flow system so as to provide environmental control (e.g., temperature control, pressure control, humidity control, air and/or coolant flow rate control, etc.) within the rack that is independent and separate from other racks in the container 20 and/or the CDCF 10. In this configuration, the controller 170 can provide direct environmental control within a rack 100, while control server 60 provides an upper level or upper tier of environmental control to one or more racks 100 based upon implemented and/or changing policies associated with the racks 100, containers 20 and/or CDCF 10. Alternatively, the environmental control server 60 can be configured to provide direct environmental control within each rack by controlling operation of the fan units and coolant flow system assigned to each rack.

Controller operation of the fan units 120 includes adjusting the fan speed (each fan unit has a plurality of operating speeds). Controller operation of the coolant flow system includes automatically adjusting valve 132 to adjust coolant flow rate through the conduit 130 between the inlet 133 and the outlet 134, and also adjusting a temperature of the coolant within the coolant flow system at a location prior to entering the rack inlet 133 (e.g., by controlling operation of the coolant source 40).

As previously described, each container 20 within the CDCF 10 can include one or more racks 100. Alternatively, one or more containers 20 can be configured as a rack 100. The design of each rack 100, including locations, number and different types of sensors associated with each rack, provides detailed information regarding environmental conditions within individual racks as well as IT workload conditions for computer components 110 at any selected time period within individual racks. All of this information is provided to the rack controllers 170 and can also be provided from the CDCF 10 to the environmental control system 50 (via link 52). The control server 60 and/or each controller 170 associated with each rack 100 is configured to provide independent temperature control as well as independent control of other environmental conditions (e.g., air pressures, humidity levels, etc.) for each individual container 20 and/or each individual rack 100 within each container 20 based upon the measured environmental conditions within each rack (e.g., air and coolant temperature conditions, humidity levels, IT workloads on computer components, etc.).

Environmental conditions are controlled within racks 100 and containers 20 within the CDCF 10 utilizing environmental control algorithms that are stored within the algorithm database 70. The environmental control algorithms are based upon different criteria or policies to be implemented for a particular rack design and/or particular specifications for a rack and/or different conditions not directly available to the rack controllers 170 or the control server 60. The system facilitates implementation of an environmental control algorithm (via the control server 60 and/or rack controllers 170) for all racks 100 within the CDCF 10 or, alternatively, implementation of different environmental control algorithms for different racks 100 within the CDCF 10 so as to provide individualized and separate environmental control (e.g., control of temperature conditions, pressure conditions, humidity conditions, air flow rate conditions, etc.) for two or more racks or two or more sets of racks within the CDCF.

Information about the computer components provided in each rack is stored within an IT equipment database 80, and this information can be utilized by the control server 60 and/or each rack controller 170 in combination with certain environmental control algorithms to be applied to a particular rack. Examples of information stored within the IT equipment database 80 include, without limitation, a listing of all computer components 110 and where each is located within a specific rack 100 that is within a specific container 20 of the CDCF 10, the computational and storage load ratings for each computer component, the redundancy and reliability requirements for each computer component (which can be used to provide a priority ranking for maintaining a particular computer component within a desired temperature range to optimize its performance), etc.

The control server 60 and/or rack controllers 170 can also use, in combination with the environmental control algorithms, information stored in a historical performance database 90. The information in the historical performance database 90 includes historical information regarding measured and recorded changes in environmental conditions (e.g., temperature changes, air pressure or air flow rate changes, etc.) over selected time periods within specific racks that include specific types of computer components. Examples of measured and recorded changes in environmental conditions within specific racks can result from a number of scenarios, such as a change in the IT workload for one or more computer components within a specific rack over a given time period (e.g., one or more computer components in a specific rack have a history of an increased IT workload during certain time periods within a day, a week, a month, etc.), and a change in ambient temperature within which the CDCF 10 is provided (e.g., a change in average ambient temperature between spring, summer, fall and winter seasons). Based upon this historical information for specific racks, the control server 60 and/or rack controllers 170 can establish a predictive model of the thermal treatment requirements (e.g., cooling or warming) for a certain time period that enhances the environmental control algorithm utilized to thermally treat a particular rack.

Thus, the environmental control system 50 and/or rack controllers 170 utilize any one or combination of: (a) direct sensor measurement feedback based upon environmental conditions within a rack (including temperature measurements at specific locations within the rack, calculated temperature gradients within the rack based upon temperature measurements from two or more sensors within the rack, air pressure measurements at one or more locations within the rack, air flow conditions at one or more locations within the rack, and humidity measurements within the rack); (b) measured IT workloads from one or more computer components within the rack; (c) known performance characteristics of computer components within the rack; (d) historical performance information that is available for the rack; and (e) other conditions that are not directly measured within or not directly associated with the rack (e.g., geographic environmental conditions in which the CDCF or a particular container or rack is located, policy changes to a particular rack, containerized data center (CDC) that houses racks, or a containerized data center farm (CDCF) that houses a plurality of CDCs, etc.) to enhance cooling, temperature and/or other types of environmental control within the rack thereby optimizing performance of the computer components within the rack. Since the temperature and other environmental conditions required for optimizing performance characteristics for one rack can differ from another rack (e.g., due to the number and/or types of computer components that differ between each rack), the control server 60 and or each individual rack controller 170 can implement different environmental control algorithms for providing separate and individualized controlled environmental conditions within each rack. The environmental control system 50 and/or each individual rack controller 170 can further dynamically change an environmental control algorithm implemented for a particular rack based upon a change in the measured data associated with the rack. In addition, two or more computer components within a rack can be controlled separately, based upon different environmental control algorithms applied to each computer component (e.g., by adjusting fan unit operational speeds differently within the same rack based upon the location of each fan unit with respect to particular components and the types of environmental control to be applied to such computer components).

The types of environmental control algorithms that can be applied to a particular rack, a CDC housing a rack, or a CDCF that houses a plurality of CDCs, will depend upon a number of factors including, without limitation, the rack design and desired performance characteristics of the computer components within the rack, the geographic location of the rack, CDC or CDCF, whether there are external factors that influence environmental control for the rack, CDC and/or CDCF based upon higher level policies, etc. Some general and non-limiting examples of criteria to be incorporated within environmental control algorithms to implement within a rack are as follows.

1. Controlling coolant temperature, coolant flow and/or the speed of one or more fan units for the rack to establish and maintain a selected temperature, humidity level, air pressure and/or air flow rate at one or more locations within the rack and/or to establish and maintain a selected gradient between at least two temperature sensors within the rack (e.g., a ΔT value between a hot aisle temperature and a cold aisle temperature within the rack). For example, in response to a measured ΔT value within the rack rising above a threshold value, the algorithm implements an increase in one or more fan unit operating speeds, an increase in the coolant flow rate (by adjusting valve 132) and/or decreasing the temperature of the coolant flowing within the conduit 130.

2. As the measured IT workloads decrease for one or more computer components within a rack below a lower threshold value, the algorithm implements a decrease in the flow of coolant and/or the operating speed of one or more fan units for the rack. In contrast, when the measured IT workloads for one or more computer components increases within the rack above an upper threshold value, the algorithm implements a corresponding increase in the flow of coolant and/or operating speed of one or more fan units.

3. When it is determined that one or more computer components within a rack is not operating (e.g., when a server management system disposed within a rack is in a shutdown mode), the algorithm implements a shut down of the coolant system and fan units. This determination can be made, for example, based upon feedback from the IT workload sensor(s) for the rack that indicates no power or a minimal amount of power has been supplied to the computer components within the rack over a selected amount of time.

4. Historical environmental control data for a rack can be established over a certain operational time period, where such historical data is stored within the historical performance database 90. An algorithm utilizes this historical performance data to implement suitable adjustments to fan unit operating speeds, coolant flow rates and/or coolant temperature and/or flow rate setpoints. For example, the historical performance data for a particular rack can indicate that, when an IT workload for one or more computer components and/or when a measured temperature gradient within the rack exceeds a certain threshold value, operating speeds for one or more fan units and/or coolant flow rate must be increased. The historical performance data can also provide specific setpoints (e.g., specific coolant valve adjustments and/or specific adjustments to the operating speed of one or more fan units) for the rack that are known to result in an efficient cooling within the rack which results in establishing an acceptable temperature gradient and/or which optimizes performance of the computer components disposed therein.

5. Utilizing known performance information, acquired from the IT equipment database 80, an algorithm implements environmental control that is tailored to the specific computer components within a particular rack. For example, if the specifications for a particular server within the rack, which are accessible from the IT equipment database 80, indicate that optimal performance conditions for a particular server are within a specified temperature range, the algorithm implements control of the fan unit operating speeds and/or coolant flow rate to achieve a setpoint temperature within the rack that is close to or within the specified temperature range for the server. The algorithm can further implement control of the fan units and coolant system to achieve a desired temperature gradient within the rack.

6. An algorithm can be implemented to monitor when an internal fan of one or more computer components is operating. Many computer components, such as servers and storage databases, have cooling fans incorporated within the housing of the component to provide cooling within the component. Additional sensors can be implemented within the rack that are coupled with computer components to provide an indication to the control server 60 and/or the rack server 170 regarding when an internal cooling fan of one or more computer components is running. The algorithm implements an integrated use of the rack fan units with the internal cooling fans of the computer components to minimize overall power consumption for the rack. For example, when a rack sensor provides an indication that an internally mounted fan within a particular computer component is running, the operating speed of one or more rack fan units that are in close proximity to this computer component are adjusted (e.g., the operating speed of a rack fan unit can be decreased).

7. An algorithm can be implemented that utilizes measured information from one or more leak detection sensors within a particular rack, where an indication by such sensors of a leak results in a warning provided by the control server 60 and/or the rack controller 170 to a system operator that there is a potential problem with the cooling system of the rack. In addition, identification of other problems associated with the cooling system, such as a potential blockage in the conduit that prohibits or significantly reduces coolant flow, performance degradation in one or more fan units, etc., can be identified based upon a comparison of current temperatures and temperature gradients within the rack vs. historical information for the rack under the same or similar IT workload conditions (available in the historical performance database 90). Changes in air flow rates, which can be measured by airflow sensors within the rack, can also provide an indication of fan unit degradation. Humidity sensors can further provide an indication when the airflow circulating within a rack has too much moisture (which could present problems with the operation of computer components within the rack). When a problem is detected, the temperature control server 60 provides a warning to the system operator.

8. The control server 60 and/or rack controller 170 can dynamically change environmental control algorithms implemented for a particular rack based upon changing conditions. For example, an initial algorithm implemented for the rack focuses on achieving a setpoint temperature at a selected location (e.g., a hot aisle location) within the rack by adjusting (as necessary) fan unit operating speeds and/or coolant flow rates within the rack. However, when the IT workload of a computer component within the rack exceeds a threshold value, a different algorithm is implemented for the rack that utilizes known setpoints for the fan units and coolant flow system that are known to optimize computer component performance based upon historical performance information stored in the historical performance database 90 for such IT workload levels associated with the rack.

9. An algorithm can be implemented to control environmental conditions within one rack, or within a plurality of racks within a CDC or a CDCF, based upon conditions that are external to and do not directly influence the rack, CDC or CDCF that is subject to environmental control. For example, an algorithm may be implemented based upon an upper tier or upper level policy in which temperatures, pressures, air and/or coolant flow rates are allowed to fall outside of certain set point ranges for a particular rack or a particular CDC within a CDCF and for a select time period in order to devote resources (e.g., coolant flows, electrical energy requirements associated with cooling the rack or CDC) to another area (e.g., another rack or another CDC within the CDCF) due to a particular crisis (e.g., significant overheating within another rack or CDC). As soon as the crisis is averted, an algorithm is implemented to bring the rack within desired environmental conditions so as to ensure optimal performance of the computer components within the rack.

The above examples can be implemented alone or in any selected combination with each other for a particular scenario.

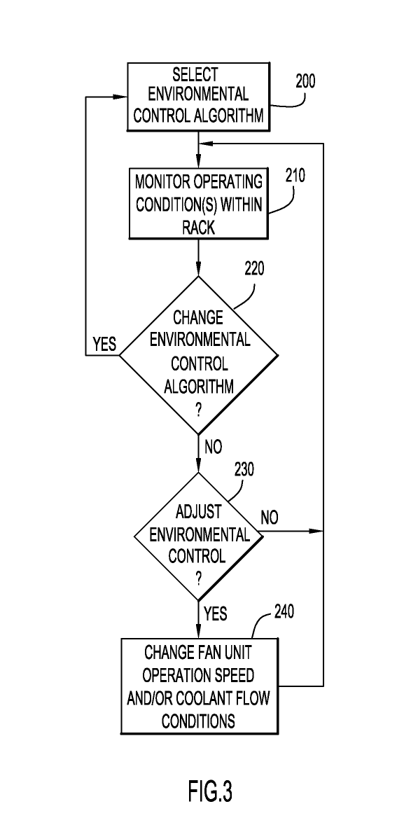

Referring to FIG. 3, a flowchart depicts an example process for implementing environmental control within a rack 100 disposed within a container 20 in a CDCF 10 utilizing the environmental control system 50 and/or the rack controller 170. Thus, the example process can be independently and separately implemented for each rack 100 within a container 20 and within the CDCF 10. At 200, the control server 60 and/or rack controller 170 initially selects an environmental control algorithm from the algorithm database 70 for controlling temperatures within the rack 100 based upon any one or combination of different criteria, such as the types of previously described criteria. The environmental control algorithm can further utilize information from one or both of the IT equipment database 80 and the historical performance database 90 in order to implement the algorithm. Based upon the selected algorithm, the control server 60 and/or rack controller 170 monitors, at 210, one or more operating conditions within the rack based upon measured information from the sensors.

At 220, the server 60 and/or rack controller 170 determines whether to change the environmental control algorithm based upon an operating condition within the rack 100 falling outside of a selected range or based upon an operating condition that is external to the rack (e.g., based upon an upper level policy to be implemented based upon a condition that is not measurable within the rack). For example, if an IT workload for a computer component suddenly increases above a threshold value, the server 60 and/or rack controller 170 may determine that such a sudden change requires a change in the approach for cooling the rack 100, where historical information associated with IT loads for the computer component may be needed to assist in developing an effective algorithm to optimize cooling and performance of the computer component within the rack. If a change in algorithm is required, the server 60 and/or rack controller 170 selects another environmental control algorithm at 200 for implementation in controlling environmental conditions within the rack.

If no change in the environmental control algorithm is necessary, at 230 the server 60 and/or rack controller 170 determines whether an environmental control adjustment is necessary based upon the measured operating conditions. If an environmental control adjustment is needed, at 240 the server 60 and/or rack controller 170 effects a change in the operational speed of one or more fan units 120 and/or a change in the coolant flow conditions (e.g., changing the coolant flow rate). The server 60 and/or rack controller 170 then continues to monitor operating conditions within the rack at 210.

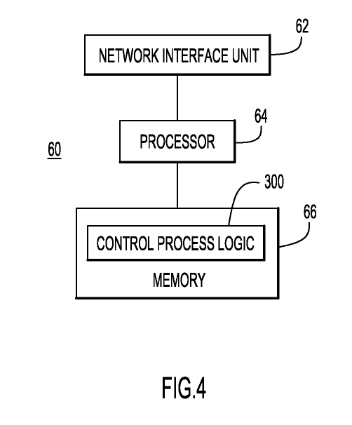

FIG. 4 shows an example of a block diagram of the server 60. The server 60 comprises a network interface unit 62, a processor 64 and a memory 66. The network interface unit 62 is, for example, an Ethernet interface card or switch, that enables communications over a network. The processor 64 is a microprocessor or microcontroller that executes software instructions stored in memory 66. The memory 66 may comprise read only memory (ROM), random access memory (RAM), magnetic disk storage media devices, optical storage media devices, flash memory devices, electrical, optical, or other physical/tangible memory storage devices. The processor 64 executes instructions for the control process logic 300 stored in memory 66. The control process logic 300, when executed by the processor 64, causes the processor to perform the operations depicted in the flow chart of FIG. 3. In general, the memory 66 may comprise one or more computer readable storage media (e.g., a memory device) encoded with software comprising computer executable instructions and when the software is executed (by the processor 64) it is operable to perform the operations described herein in connection with process logic 300. Each rack controller 170 includes the same or similar configuration as shown in FIG. 4 for the control server 60. Thus, the processor and control process logic as shown in FIG. 4 facilitate implementation of environmental control algorithms to control the fan units 120 and coolant flow system of the racks 100 in response to measured conditions associated with each rack (obtained by information communicated to the rack controller 170 or the control server 60 by the various sensors associated with the rack) or external conditions that may affect the type of control algorithm to be applied to each rack.

Environmental control algorithms can be implemented and/or changed within a rack 100 by the control server 60, the rack controller 170 or a combination of both the control server 60 and rack controller 170. In an example embodiment, each rack controller 170 can directly access the databases 70, 80, 90 (via communication link 52) and apply an environmental control algorithm to the rack 100. Changes to the algorithm can also be implemented by the rack controller 170, based upon changing operating conditions within the rack or a condition that is external to the rack (i.e., a condition that is not measurable within or associated with the rack).

Alternatively, the control server 60 can function as an upper tier or upper level management controller that provides algorithms to individual rack controllers 170 and implements changes in an environmental control algorithm to a particular rack 100 based upon an external condition. Thus, the rack controller 170 can be configured to implement operation of the selected algorithm locally by controlling the fan units 120 and or coolant flow system accordingly, while the control server 60 implements upper level control on each rack 100 based upon policies to be applied to a particular rack, a particular CDC and/or a particular CDCF. The environmental control system 50 can further be in communication with any number of different CDCs, CDCFs or even individual racks that are in different geographical locations, where the control server 60 provides a centralized, remote control location for control of environmental conditions for computer components located at a number of different facilities.

The methods and systems described herein provide individualized, dynamic and efficient cooling and/or other environmentally controlled conditions for computer components within rack systems based upon sensor readings within racks, IT workloads, historical temperature control information and performance specifications for computer components. This allows for finer grained power optimization for controlling temperature in comparison to traditional temperature control systems, particularly when utilized in containerized data centers incorporating a large number of computer components in multiple rack structures. The methods and systems further allow for remote environmental control within racks, where the environmental control can be independently and separately implemented for different racks and also based upon separate policies associated with different racks (or different containers containing multiple racks).

The above description is intended by way of example only.

What is claimed is:

1. A method comprising:
in a computer component rack comprising at least one computer component and a thermal treatment system configured to control an environmental condition for the at least one computer component within the rack, measuring an operating condition comprising a condition associated with the at least one computer component in the rack;
selecting an algorithm from a plurality of environmental control algorithms stored within a database; and
in response to the measured operating condition falling outside of a setpoint range, thermally treating the at least one computer component via the thermal treatment system and in accordance with the selected algorithm.

2. The method of claim 1, wherein the selected algorithm depends upon at least one of a type of computer component within the rack and historical performance information of the at least one computer component within the rack.

3. The method of claim 2, and further comprising dynamically changing from the selected algorithm to another algorithm during operation of the rack based upon at least one of a change in the measured operating condition and a change of second measured condition, wherein the second measured condition comprises at least one of a second measured operating condition associated with the at least one computer component within the rack and a measured condition external to the rack.

4. The method of claim 1, wherein the measured operating condition comprises a workload of the at least one computer component.

5. The method of claim 1, wherein the rack is disposed in a container with a second rack, and temperature control within each rack is independently maintained by separately monitoring at least one operating condition associated with at least one computer component within each rack.

6. The method of claim 1, wherein the thermal treatment by the thermal treatment system comprises at least one of adjusting a fan operating speed and a coolant flow rate within the rack.

7. The method of claim 1, wherein thermal treatment by the thermal treatment system is adjusted based upon operation of a fan located within the at least one computer component.

8. A system comprising:
a containerized data center comprising a rack, at least one computer component disposed within the rack, at least one sensor to measure an operating condition of the at least one computer component disposed within the rack, and a thermal treatment system to control an environmental condition for the at least one computer component within the rack;
a database including a plurality of algorithms configured to control environmental conditions of the at least one computer component within the rack; and
a controller to select an algorithm from the database and to control the thermal treatment system, wherein in response to the measured operating condition of the at least one computer component within the rack falling outside of a setpoint range, the controller controls the thermal treatment system utilizing the selected algorithm to thermally treat the at least one computer component.

9. The system of claim 8, wherein the selected algorithm is dependent upon at least one of a type of computer component within the rack and historical performance information of the at least one computer component within the rack.

10. The system of claim 9, wherein the controller is configured to dynamically switch from the selected algorithm to another algorithm during operation of the rack based upon at least one of a change in the measured operating condition and a change of second measured condition, wherein the second measured condition comprises at least one of a second measured operating condition associated with the at least one computer component within the rack and a measured condition external to the rack.

11. The system of claim 8, wherein the measured operating condition comprises a workload of the at least one computer component.

12. The system of claim 8, wherein the thermal treatment system comprises at least one rack fan, and the controller controls the cooling system by adjusting an operating speed of the at least one rack fan.

13. The system of claim 12, wherein the thermal treatment system further comprises a coolant flow conduit that provides flowing coolant within the rack, and the controller further controls the cooling system by adjusting a coolant flow rate within the rack.

14. The system of claim 8, wherein the at least one computer component includes a fan located within the computer component, and the controller further controls operation of the thermal treatment system dependent upon operation of the fan located within the at least one computer component.

15. The system of claim 8, wherein the containerized data center further comprises a plurality of racks, and the controller separately and independently controls cooling for at least two racks based upon different algorithms associated with the at least two racks.

16. An environmental control system configured for use with a containerized data center, the containerized data center comprising a rack, at least one computer component disposed within the rack, at least one sensor to measure an operating condition of the at least one computer component disposed within the rack, and a thermal treatment system to thermally treat the at least one computer component within the rack, the temperature control system comprising:
a database including a plurality of algorithms configured to control environmental conditions of the at least one computer component within the rack, wherein at least one algorithm is dependent upon at least one of a type of computer component within the rack and at least another algorithm is dependent upon historical performance information of the at least one computer component within the rack; and
a controller to control the thermal treatment system of the containerized data center utilizing an algorithm selected from the database, wherein in response to the measured operating condition of the at least one computer component falling outside of a setpoint range, the controller controls the thermal treatment system to thermally treat the at least one computer component utilizing the selected algorithm.

17. The system of claim 16, wherein the controller is configured to dynamically switch from the selected algorithm to another algorithm during operation of the rack based upon at least one of a change in the measured operating condition and a change of second measured condition, wherein the second measured condition comprises at least one of a second measured operating condition associated with the at least one computer component within the rack and a measured condition external to the rack.

18. The system of claim 16, wherein the measured operating condition comprises a workload of the at least one computer component.

19. The system of claim 16, wherein the at least one computer component includes a fan located within the computer component, and the controller further controls operation of the thermal treatment system dependent upon operation of the fan located within the at least one computer component.

20. The system of claim 16, wherein the containerized data center further comprises a plurality of racks, and the controller separately and independently controls cooling for at least two racks based upon different algorithms associated with the at least two racks.

21. One or more computer readable storage media encoded with software comprising computer executable instructions and when the software is executed operable to:
generate a measure of an operating condition of at least one computer component in a computer component rack that includes a thermal treatment system configured to provide thermal treatment to the at least one computer component within the rack;
select an algorithm from a plurality of environmental control algorithms stored within a database; and
in response to the measured operating condition of the at least one computer component within the rack falling outside of a setpoint range, generate a control to thermally treat the at least one computer component utilizing the selected algorithm.

22. The computer readable storage media of claim 21, wherein the selected algorithm depends upon at least one of a type of computer component within the rack and historical performance information of the at least one computer component within the rack.

23. The computer readable storage media of claim 22, and further comprising instructions that are operable to dynamically change from the selected algorithm to another algorithm during operation of the rack based upon at least one of a change in the measured operating condition and a change of second measured condition, wherein the second measured condition comprises at least one of a second measured operating condition associated with the at least one computer component within the rack and a measured condition external to the rack.
